(19) United States
(12) Patent Application Publication
(10) Pub. No.: US 2007/0079934 A1
(43) Pub. Date: Apr. 12, 2007

(54) Gas dispersion plate and manufacturing method therefor

(75) Inventors: Yukitaka Murata, Aichi (JP); Sachiyuki Nagasaka, Aichi (JP); Keiji Morita, Aichi (JP); Keisuke Watanabe, Aichi (JP); Shigenori Wakabayashi, Aichi (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 11/512,431

(22) Filed: Aug. 30, 2006

(30) Foreign Application Priority Data
Aug. 31, 2005 (JP) P. 2005-252797
Sep. 9, 2005 (JP) P. 2005-262627

(51) Int. Cl. H01L 21/306; C23F 1/00; C23C 16/00

(52) U.S. Cl. 156/345.34; 156/345.33; 118/715; 156/914

(57) ABSTRACT

To provide an inexpensive gas dispersion plate having a high corrosion resistance to halogen-based corrosive gasses and a plasma thereof, and capable of preventing particle generation from the gas hole, thereby contributing to an improvement in the production yield of the semiconductor devices. The gas dispersion plate includes one or plural gas holes in a base material formed by a Y₂O₃ ceramic material having a relative density of 96% or more, in which an edge part of the gas hole is formed by a sand blasting process into a rounded shape with a radius of curvature of 0.2 mm or more.

### TECHNICAL FIELD

The present invention relates to a gas dispersion plate and a manufacturing method therefor, and more particularly to a gas dispersion plate in which an edge part of a gas hole is formed into a rounded shape by a sand blast process, to a gas dispersion plate in which a gas hole is formed under application of an ultrasonic vibration to a working jig, and a manufacturing method therefor.

### BACKGROUND ART

In a semiconductor manufacturing apparatus such as an etching apparatus, a shower plate is provided directly above a wafer, for the purpose of uniformly dispersing a reactive gas.

Such shower plate is commonly prepared with anodized aluminum, but, with an increasing density of plasma, various problems have become conspicuous, such as an aluminum contamination from the shower plate and particle (dust) generation by a peeling of the anodized film.

In order to avoid such drawbacks, it has been tried to coat the surface of the shower plate with a corrosion resistant material such as alumina or Y₂O₃ for example by a thermal spraying (see Japanese Patent Unexamined Publication JP-A-2000-315680). However, a problem of peeling-off of the thermally sprayed film has been frequently encountered because of an insufficient adhesion strength of the thermally sprayed film around the shower hole or of a difference in the thermal expansion during the use. Also a deterioration in the adhesion strength of the film by repeated washings has been a problem.

So, a sintered member of alumina or Y₂O₃ is recently jointed by adjoining or by screwing on a surface of the shower plate.

However, the particles from the shower plate cannot be completely eliminated, even in such shower plate on which a highly corrosion resistant material is adjoined or jointed. Such particles are generated by dropping of the ceramic material (alumina or Y₂O₃) adjoined to or jointed on the shower plate or peeling of a reaction product, deposited on the shower plate, onto the wafer positioned thereunder.

Further, a sintered Y₂O₃ member is recently employed because of a high plasma resistance thereof (see Japanese Patent Unexamined Publication JP-A-2003-234300).

However, aluminum or alumina has a low plasma resistance, and tends to generate particles when exposed to a plasma. A thermal spraying of Y₂O₃ allows to suppress the particle generation to a certain extent in a thermally sprayed part. However, spraying the Y₂O₃ to execute in an interior (internal surface) of a gas hole of a diameter of about 1 mm is technically difficult. Also a bulk Y₂O₃ material, though having a plasma resistance better in thermal spraying, generates particles because of scratches and crush layer formed at the hole formation.

### SUMMARY OF THE INVENTION

As a result of intensive investigations undertaken by the present inventors, it is found that the particles generated from the ceramic material adjoined or jointed to the shower plate are mostly derived from an edge part of gas holes (shower holes), and that an adhesion strength of the reaction product is influenced by a surface roughness and a shape of a portion where the reaction product is deposited, and the present invention has thus been made.

More specifically, ceramics such as alumina or Y₂O₃ are brittle materials, and a worked face of a sintered member includes a crush layer. An edge part of the gas hole contains many particles that are about to drop, and particles that could not be removed by washing drop onto the wafer in the course of use. It is also tried to remove the edge part by a chamfering, but it is impractically costly and time-consuming to execute a tooling on each of several hundred to several thousand holes present per a shower plate.

As to the adhesion strength of the film of the reaction product, a rougher surface in the deposited part of the base material provides a larger anchoring effect to the base material, thus showing less peeling.

Also the adhesion strength of the film of the reaction product, deposited on the edge part of the gas hole, increases in the order of: no chamfering < chamfering < round chamfering, and it is thus found that a round shape without a corner part or a ridge part is effective.

A film deposited on a corner or ridge portion does not have an adhesion strength and is easily peeled off. In case of a non-chamfered surface, presence of many particles that are about to drop is also a factor for particle generation.

The present invention is to solve these problems with a low cost. More specifically, a sand blasting is used to form a rough surface in the vicinity of the gas hole and to simultaneously execute a round chamfering on an edge part of the gas hole. The edge part of the obtained shower plate shows a rounded shape without a corner or a ridge, and shows a strong adhesion due to a rough surface formed by the blasting. Also the absence of a corner or sharp part, where an electrostatic charge tends to be accumulated, allows to avoid a breakage of ceramics, occasionally induced by an electric arc. Such shower plate allows to prevent particle generation from the gas holes, experienced in the prior technology, and contributes to an improvement in the production yield of semiconductor devices.

The present invention has been made in consideration of the aforementioned situation, and an object thereof is to provide an inexpensive gas dispersion plate having a high corrosion resistance to halogen-based corrosive gasses and a plasma thereof, and capable of preventing particle generation from the gas hole, thereby contributing to an improvement in the production yield of semiconductor devices.

Another object of the present invention is to provide a manufacturing method for a gas dispersion plate, having a high corrosion resistance to halogen-based corrosive gasses and a plasma thereof, and capable of preventing particle generation from the gas hole, thereby contributing to an improvement in the production yield of the semiconductor devices.

For accomplishing the aforementioned objects, according to one of aspects of the present invention, there is provided a gas dispersion plate comprising a base material comprising Y₂O₃ ceramics of which relative density is 96% or more, one or plural gas holes in the base material,

wherein an edge part of the gas hole is formed by a sand blasting process into a rounded shape with a radius of curvature of 0.2 mm or more.

According to one of aspects of the present invention, there is provided a manufacturing method for a gas dispersion plate comprising the steps of:
adding water and a binder to a Y₂O₃ raw material to obtain a slurry;
forming the slurry into granules by a spray-dryer;
press molding the obtained granules to obtain a molded member;
calcining the molded member to evaporate the binder;
sintering the molded member to obtain a sintered Y₂O₃ ceramic member with a relative density of 96% or more;
forming one or plural gas holes on the sintered member; and
performing a sand blasting process on an edge part of the gas hole so as to form a rounded shape.

According to one of aspects of the present invention, there is provided a gas dispersion plate comprising: a base material comprising Y₂O₃ ceramic of which purity is 99% or more;
one or plural gas holes formed in the base material wherein the base material is sintered at temperature of from 1780 to 1820° C. in a hydrogen atmosphere, and the gas hole is formed while applying an ultrasonic vibration to a working jig.

According to one of aspects of the present invention, there is provided a manufacturing method for a gas dispersion plate comprising the steps of:
adding water and a binder to a Y₂O₃ raw material of a purity of 99% or higher to obtain a slurry;
forming the slurry into granules by a spray-dryer;
press molding the obtained granules to obtain a molded member;
calcining the molded member to evaporate the binder;
sintering the molded member at a temperature of from 1780 to 1820° C. in a hydrogen atmosphere to obtain a sintered Y₂O₃ ceramic member; and
forming one or plural gas holes in the sintered member under an application of an ultrasonic vibration to a working jig.
The present invention enables to provide an inexpensive gas dispersion plate having a high corrosion resistance to halogen-based corrosive gasses and a plasma thereof, and capable of preventing particle generation from the gas hole, thereby contributing to an improvement in the production yield of the semiconductor devices.

The present invention also enables to provide a manufacturing method for a gas dispersion plate, having a high corrosion resistance to halogen-based corrosive gasses and a plasma thereof, and capable of preventing particle generation from the gas hole, thereby contributing to an improvement in the production yield of the semiconductor devices.

### BRIEF DESCRIPTION OF THE DRAWINGS

FIG. 1 is a perspective view of an embodiment of the gas dispersion plate of the present invention;

FIG. 2 is a longitudinal cross-sectional view of an embodiment of the gas dispersion plate of the present invention; and

FIG. 3 is a schematic view of an etching apparatus utilizing the gas dispersion plate of the present invention.

### DETAILED DESCRIPTION OF THE PREFERRED EMBODIMENTS

In the following, an embodiment of the gas dispersion plate of the present invention will be explained with reference to the accompanying drawings.

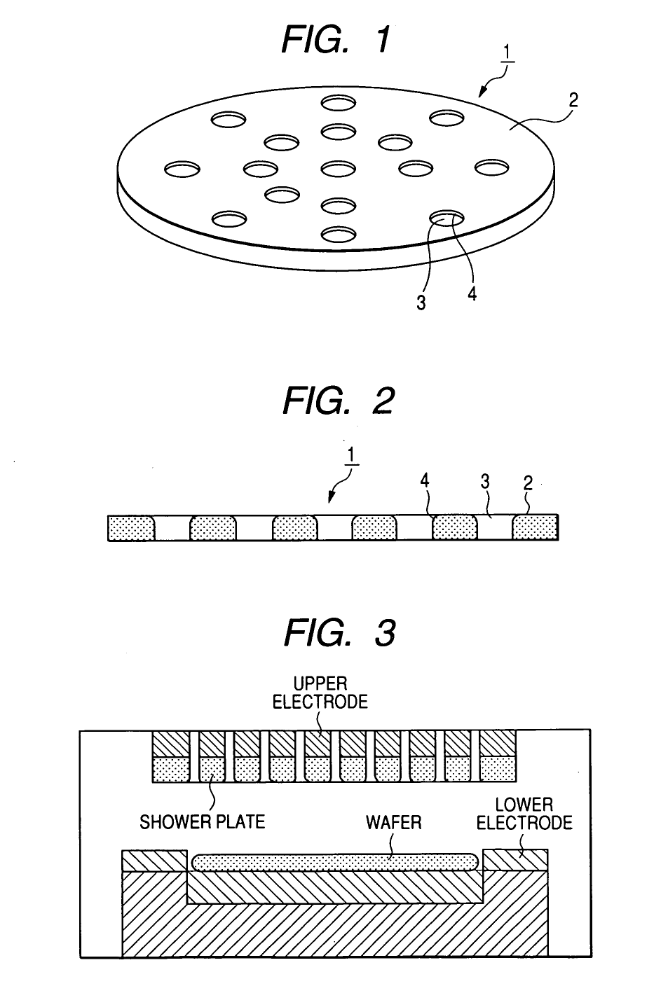

FIG. 1 is a perspective view of a gas dispersion plate of the present invention, and FIG. 2 is a longitudinal cross-sectional view thereof.

As shown in FIGS. 1 and 2, a gas dispersion plate 1 constituting a shower plate has one or plural gas holes 3 in a base material 2 formed by a Y₂O₃ ceramic material having a relative density of 96% or more, and an edge part 4 of the gas hole 3 is formed by a sand blasting process into a rounded shape with a radius of curvature of 0.2 mm or more.

A relative density of Y₂O₃ of 96% or more is selected, because a lower density results in a significant damage by the sand blast process due to an increased proportion of pores, thus rather facilitating the particle generation. Also a rounded shape with a radius of curvature less than 0.2 mm is not effective for the adhesion strength of the film.

The present embodiment realizes an inexpensive gas diffusion plate capable of preventing the edge part of the gas hole from dropping off and preventing particle generation from the gas hole, thereby contributing to an improvement in the production yield of the semiconductor devices, even when the gas diffusion plate is exposed to a plasma gas of a halogen compound such as CCl₄, BCl₃, HBr, CF₄, C₄F₈, NF₃ or SF₆, a highly corrosive self-cleaning ClF₃ gas or a strong sputtering plasma utilizing N₂ or O₂, in the course of a surface film process on a semiconductor wafer, because the base material itself constituted of a Y₂O₃ material of a relative density of 96% or more allows to prevent an etching of the base material, also to prevent an etching of the base material by an electrostatic discharge inside the gas hole, and to improve the corrosion resistance of the surface of the gas hole, and because the edge part of the gas hole is formed by a sand blasting process into a rounded shape with a radius of curvature of 0.2 mm or more. Also such rounded shape allows avoiding the particle generation, caused by a dropping of the edge part, with a low cost.

The gas diffusion plate of the present embodiment can be produced by a following method.

It is prepared by adding water and a binder to a Y₂O₃ raw material to obtain a slurry, forming the slurry into granules by a spray-dryer, press molding the obtained granules to obtain a molded member, calcining the molded member to evaporate the binder, sintering the molded member to obtain a sintered Y₂O₃ ceramic member with a relative density of 96% or more, forming one or plural holes on the sintered member, and executing a sand blasting process to form an edge part of the gas hole into a rounded shape.

The manufacturing method of the embodiment allows to obtain a gas dispersion plate, having a high corrosion resistance to halogen-based corrosive gasses and a plasma thereof, and capable of preventing particle generation from the gas hole, thereby contributing to an improvement in the production yield of the semiconductor devices.

### EXAMPLES

Ion-exchanged water and a binder were added to an Y₂O₃ raw material having a purity of 99.9% to obtain slurry, which was formed into granules by a spray-dryer. The obtained granules were molded under a pressure of 1500 kgf/cm² to obtain a base material. After the binder was eliminated by a calcining, it was sintered at 1800° C. in a hydrogen atmosphere to obtain a sintered member having a relative density of 96% or more and a dimension of 320 mm (diameter)×3 mm (thickness). In the sintered member, 300 shower holes of a diameter of 0.5 mm were formed (Examples 1-1 to 1-5, and Comparative Examples 1-1 to 1-4). Also a sintered member having a relative density of 95 was obtained by changing the molding pressure and the sintering temperature, and similarly processed (Comparative Examples 1-5, 1-6).

An edge shape was formed, on these Examples 1-1 to 1-5 and Comparative Examples 1-1 to 1-6, by working methods as shown in Table 1.

A blasting was conducted with GC #240, under an emission pressure of 0.3 MPa. Each of the obtained samples was so adjoined that the gas holes match in positions, installed as a shower plate in a chamber of an etching apparatus for a 300 mm wafer as shown in FIG. 3, and subjected to an evaluation for particles. The density of the sintered Y₂O₃ member was measured by an Archimedes method. A particle count was obtained by measuring particles (0.2 μm or more) on a 300 mm wafer, by a laser particle counter.

Obtained results are shown in Table 1.

TABLE 1

| | relative | | | |
|---|---|---|---|---|
| | density | working | edge part | particle count |
| Sample | (%) | method | shape | (/300 mm wafer) |
| Comp. Ex. 1-1 | 98 | grinding | sharp edge | 22 |
| Comp. Ex. 1-2 | 98 | grinding | C0.5 | 15 |
| Comp. Ex. 1-3 | 98 | grinding | R0.5 | 10 |
| Example 1-1 | 98 | blasting | R0.5 | 3 |
| Example 1-2 | 98 | blasting | R0.8 | 5 |
| Example 1-3 | 98 | blasting | R1.0 | 5 |
| Example 1-4 | 98 | blasting | R0.2 | 6 |
| Comp. Ex. 1-4 | 98 | blasting | R0.1 | 11 |
| Example 1-5 | 96 | blasting | R0.5 | 5 |
| Comp. Ex. 1-5 | 95 | blasting | R0.3 | 25 |
| Comp. Ex. 1-6 | 95 | blasting | R0.5 | 20 |

As will be seen from Table 1, Example 1-1, meeting the conditions of the invention (relative density of 96% or more, sand blasted and rounded shape with a radius of curvature of 0.2 mm or more) and having a shape of R0.5 mm (R XX mm means that the curvature at the rounded shaped is xx mm.), showed a smallest particle count of 3. Also Examples 1-2, 1-3 and 1-4, meeting the conditions of the invention and having respectively of R0.8, R1.0 and R0.2 mm, showed particle counts of 6 or less, smallest next to Example 1-1. Also Example 1-5, meeting the conditions of the invention and having a relative density of 96%, showed a particle count as little as 5.

On the other hand, Comparative Example 1-1, utilizing a grinding method and having a sharp edge part thus not meeting the conditions of the invention, showed a particle count as extremely high as 22, which was more than 7 times of that in Example 1-1. Also Comparative Example 1-2, utilizing a grinding method, also having an edge part of C0.5 mm and thus not meeting the conditions of the invention, showed a particle count 15, which was as high as 5 times of that in Example 1-1. Comparative Example 1-3, utilizing a grinding method not meeting the conditions of the invention, showed a particle count 10, which was more than 3 times of that in Example 1-1. Comparative Example 1-4, having an edge part shape of R0.1 mm which does not meeting with the conditions of the invention, showed a particle count 11, which was more than 3 times of that in Example 1-1. Comparative Example 1-5, having a relative density different from the conditions of the invention but having R0.3 mm within the conditions of the invention, showed a particle count as extremely high as 25, which was more than 8 times of that in Example 1-1. Comparative Example 1-6, having a relative density different from the conditions of the invention but having R0.5 mm within the conditions of the invention, showed a particle count as extremely high as 20, which was more than 6 times of that in Example 1-1.

In the following, another embodiment of the gas dispersion plate of the present invention will be explained with reference to the accompanying the same drawings.

As shown in FIGS. 1 and 2, a gas dispersion plate 1 constituting a shower plate has one or plural gas holes 3 in a Y₂O₃ ceramic base material 2 formed from a Y₂O₃ raw material of a purity of 99% or higher by a sintering at a temperature of from 1780 to 1820° C. in a hydrogen atmosphere, in which the gas hole 3 is formed by applying an ultrasonic vibration to a working jig at the hole formation.

The gas diffusion plate of the present embodiment is capable of preventing particle generation from the gas hole, thereby contributing to an improvement in the production yield of the semiconductor devices, even when the gas diffusion plate is exposed to a plasma gas of a halogen compound such as CCl₄, BCl₃, HBr, CF₄, C₄F8, NF₃ or SF₆, a highly corrosive self-cleaning ClF₃ gas or a strong sputtering plasma utilizing N₂ or O₂, in the course of a surface film process on a semiconductor wafer in an etching apparatus as shown in FIG. 3, because the base material itself, formed from a Y₂O₃ raw material of a purity of 99% or higher by a sintering at a temperature of from 1780 to 1820° C. in a hydrogen atmosphere, has a high corrosion resistance to the halogen-based corrosive gasses or a plasma thereof and because formation of scratches in the gas hole and crush layer at the working is suppressed.

The gas diffusion plate of the present embodiment can be produced by a following method.

It is prepared by adding water and a binder to a Y₂O₃ raw material of a purity of 99% or higher to obtain a slurry, forming the slurry into granules by a spray-dryer, press molding the obtained granules to obtain a molded member, calcining the molded member to evaporate the binder, sintering the molded member at a temperature of from 1780 to 1820° C. in a hydrogen atmosphere to obtain a sintered Y₂O₃ ceramic member, and forming one or plural gas holes in the sintered member under an application of an ultrasonic vibration to a working jig.

A purity of the raw material less than 99% reduces the plasma resistance. Also the sintered executed in a non-hydrogen atmosphere, for example in air, lowers the purity of the sintered member, thereby reducing the plasma resistance. Also an ultrasonic vibration, applied to a working jig (such as a tool) used for hole formation, allows suppressing scratches and a crush layer, formed at the working.

The manufacturing method of the embodiment allows to obtain a gas dispersion plate, having a high corrosion resistance to halogen-based corrosive gasses and a plasma thereof, and capable of preventing particle generation from the gas hole, thereby contributing to an improvement in the production yield of the semiconductor devices.

### EXAMPLES

A shower plate was produced under the conditions shown in Table 2, was mounted in an etching apparatus as shown in FIG. 3, and subjected, in an etching of a semiconductor wafer, to an evaluation for particles, by counting particles deposited on the wafer, with a laser particle counter.

Obtained results are shown in Table 2.

TABLE 2

| | raw | | | | |
|---|---|---|---|---|---|
| | material | | sintering | | |
| | purity | sintering | temp. | ultrasonic | particles |
| Sample | (%) | atmosphere | (° C.) | vibration | (count) |
| Example 2-1 | 99.5 | hydrogen | 1800 | used | 8 |
| Comp. Ex. 2-1 | 98 | hydrogen | 1800 | used | 50 |
| Comp. Ex. 2-2 | 99.5 | hydrogen | 1750 | used | 25 |
| Comp. Ex. 2-3 | 99.5 | air | 1700 | used | 70 |
| Comp. Ex. 2-4 | 99.5 | hydrogen | 1800 | none | 45 |

As will be seen from Table 2, Example 2-1 meeting the conditions of the invention (Y₂O₃ with a raw material purity of 99% or higher, sintering at 1780-1820° C. in hydrogen atmosphere and ultrasonic vibration to working jig) showed a particle count as little as 8.

On the other hand, Comparative Example 2-1, having a raw material purity of 98% and not meeting the condition for the raw material purity, showed a particle count as extremely high as 50, which was more than 6 times of that in Example 2-1. Also Comparative Example 2-2, utilizing a sintering temperature of 1750° C. and not meeting the temperature condition, showed a particle count 25, which was more than 3 times of that in Example 2-1. Comparative Example 2-3, utilizing a sintering in the air and not meeting the condition for sintering atmosphere, showed a particle count as extremely high as 70, which was more than 8 times of that in Example 2-1. Comparative Example 2-4, not utilizing the ultrasonic vibration and not meeting the condition for vibration, showed a particle count as extremely high as 45, which was more than 5 times of that in Example 2-1.

While there has been described in connection with the preferred embodiments of the present invention, it will be obvious to those skilled in the art that various changes and modification may be made therein without departing from the present invention, and it is aimed, therefore, to cover in the appended claim all such changes and modifications as fall within the true spirit and scope of the present invention.

What is claimed is:

1. A gas dispersion plate comprising a base material comprising Y₂O₃ ceramics of which relative density is 96% or more, one or plural gas holes in the base material,
wherein an edge part of the gas hole is formed by a sand blasting process into a rounded shape with a radius of curvature of 0.2 mm or more.

2. A manufacturing method for a gas dispersion plate comprising the steps of:
adding water and a binder to an Y₂O₃ raw material to obtain slurry;
forming the slurry into granules by a spray-dryer;
press molding the obtained granules to obtain a molded member;
calcining the molded member to evaporate the binder;
sintering the molded member to obtain a sintered Y₂O₃ ceramic member with a relative density of 96% or more;
forming one or plural gas holes on the sintered member; and
performing a sand blasting process on an edge part of the gas hole so as to form a rounded shape.

3. A gas dispersion plate comprising:
a base material comprising Y₂O₃ ceramic of which purity is 99% or more;
one or plural gas holes formed in the base material,
wherein the base material is sintered at temperature of from 1780 to 1820° C. in a hydrogen atmosphere, and
the gas hole is formed while applying an ultrasonic vibration to a working jig.

4. A manufacturing method for a gas dispersion plate comprising the steps of:
adding water and a binder to a Y₂O₃ raw material of a purity of 99% or higher to obtain a slurry;
forming the slurry into granules by a spray-dryer;
press molding the obtained granules to obtain a molded member;
calcining the molded member to evaporate the binder;
sintering the molded member at a temperature of from 1780 to 1820° C. in a hydrogen atmosphere to obtain a sintered Y₂O₃ ceramic member; and
forming one or plural gas holes in the sintered member under an application of an ultrasonic vibration to a working jig.
